(19) United States
(12) Patent Application Publication
(10) Pub. No.: US 2010/0241838 A1
(43) Pub. Date: Sep. 23, 2010

(54) METHOD AND SYSTEM FOR FIRMWARE UPDATES

(76) Inventors: Jason Cohen, Austin, TX (US); Gerard L. Cullen, Austin, TX (US); Pedro DeKeratry, Austin, TX (US); Ron McCormack, Austin, TX (US)

Correspondence Address: SUITER SWANTZ PC LLO, 14301 FNB PARKWAY, SUITE 220, OMAHA, NE, 68154, US

(21) Appl. No.: 12/408,470

(22) Filed: Mar. 20, 2009

(51) Int. Cl. G06F 15/177; G06F 15/16; G06K 5/04; H04L 1/08; H03M 13/09; G06F 11/10; G06F 11/14; G06F 11/00

(52) U.S. Cl. 713/2; 713/1; 709/219; 714/699; 714/748; 714/807; 714/E11.024; 714/E11.131; 714/E11.032

(57) ABSTRACT

A method for updating computing device firmware may comprise: (a) receiving a transmission of firmware update data; (b) writing the firmware update data to a firmware update data partition; and (c) writing the firmware update data to an active firmware partition.

A system for updating computing device firmware comprising: (a) means for receiving a transmission of firmware update data; (b) means for writing the firmware update data to a firmware update data partition; and (c) means for writing the firmware update data to an active firmware partition.

### BACKGROUND

Small, diskless computer systems, also called “embedded” computer systems are used in thousand of applications such as industrial controls, medical instrumentation, and navigation devices.

There are no disk drives on these computer systems. When new or repaired programs, usually called “firmware,” are available, the user may be required to attach a cable to a data port and load the new programs directly into the embedded computer's memory. With the advent of the Internet, it has become common for the firmware be updated using Internet protocols and dedicated web servers.

However, the Internet's packet-based communications format and susceptibility to interruptions and outages may make the transfer of data difficult. Referring to FIGS. 1 and 2, a typical problem may involve transferring a complete binary file (i.e. ready-to-run code) over an Internet connection. For example, an embedded computing system 104 may comprise a system memory 105 including a random access memory (RAM) partition 106, a boot partition 107, and an original firmware partition 108-1.

A user may attempt to load firmware update data 102 from a firmware update server 101 linked to the embedded computing system 104 via a communications network 103 (e.g. the Internet). As depicted in FIG. 2, the original firmware 108-1 may be overwritten by the firmware update (e.g. memory locations 0x0000 to 0xAAA9 of the firmware partition 108 may be overwritten with instructions 0x0000 to 0xAAA9 of the firmware update 102). It may be the case that the loading of the firmware update 102 to the embedded computing system 104 may take an extended period of time (e.g. five minutes or more). During this time, the communications network 103 link may be lost and the session terminated by the TCP layer of the Internet protocol stack.

As a result, the embedded computing system 104 may be left with partially updated firmware (e.g. instructions 0x0000 through 0xAAA9 of the firmware update 102 may have been written to the firmware partition 108). Such a condition may render the system inoperative thereby requiring the user to send the entire embedded computing system 104 back to the manufacturer where a technician may load the firmware update 102 using a direct-to-memory cable set.

As such it would be desirable to provide a method and system for reliable firmware updates.

### SUMMARY

The present disclosure is directed to systems and methods for reliable firmware updates.

A method for updating computing device firmware may comprise: (a) receiving a transmission of firmware update data; (b) writing the firmware update data to a firmware update data partition; and (c) writing the firmware update data to an active firmware partition.

A system for updating computing device firmware comprising: (a) means for receiving a transmission of firmware update data; (b) means for writing the firmware update data to a firmware update data partition; and (c) means for writing the firmware update data to an active firmware partition.

It is to be understood that both the foregoing general description and the following detailed description are exemplary and explanatory only and are not necessarily restrictive of the claims. The accompanying drawings, which are incorporated in and constitute a part of the specification, illustrate examples and together with the general description, serve to explain the principles of the disclosure.

### BRIEF DESCRIPTION OF THE DRAWINGS

The numerous advantages of the disclosure may be better understood by those skilled in the art by reference to the accompanying figures in which:

FIG. 1 illustrates a firmware update system.

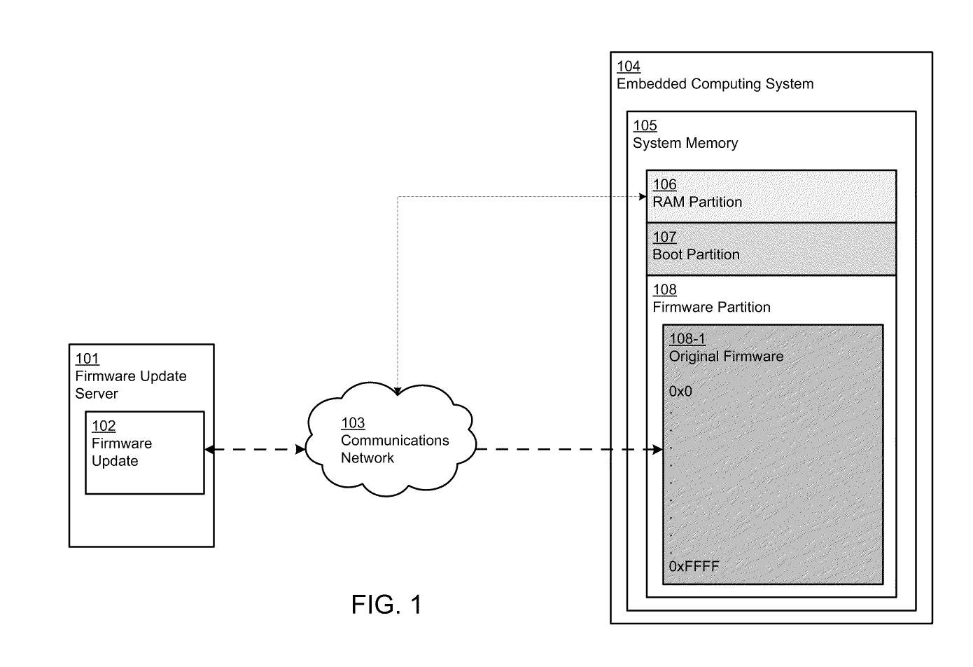

FIG. 2 illustrates a connection failure in a communications network.

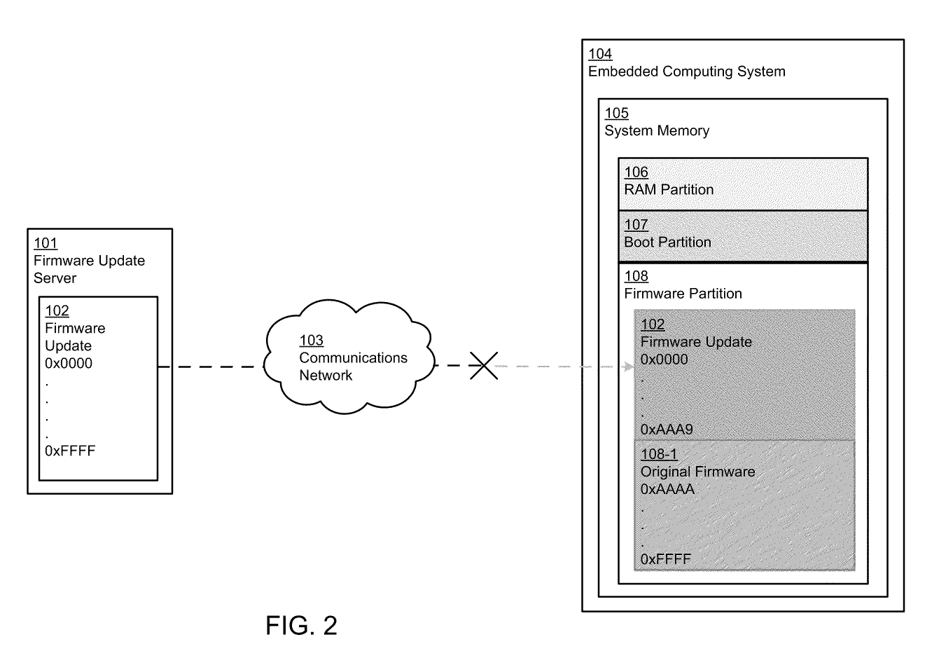

FIG. 3 illustrates receiving a firmware update transmission.

FIG. 4 illustrates writing to a firmware update partition.

FIG. 5 illustrates transferring to the active firmware partition.

FIG. 6 illustrates booting an active firmware partition.

FIG. 7 illustrates a firmware update data file configuration.

FIG. 8 illustrates an overview of the firmware update process.

FIG. 9 illustrates receiving a transmission of firmware update data.

FIG. 10 illustrates writing firmware to a firmware update partition.

FIG. 11 illustrates booting based on a firmware transfer switch.

FIG. 12 illustrates detecting a failed firmware transfer.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here.

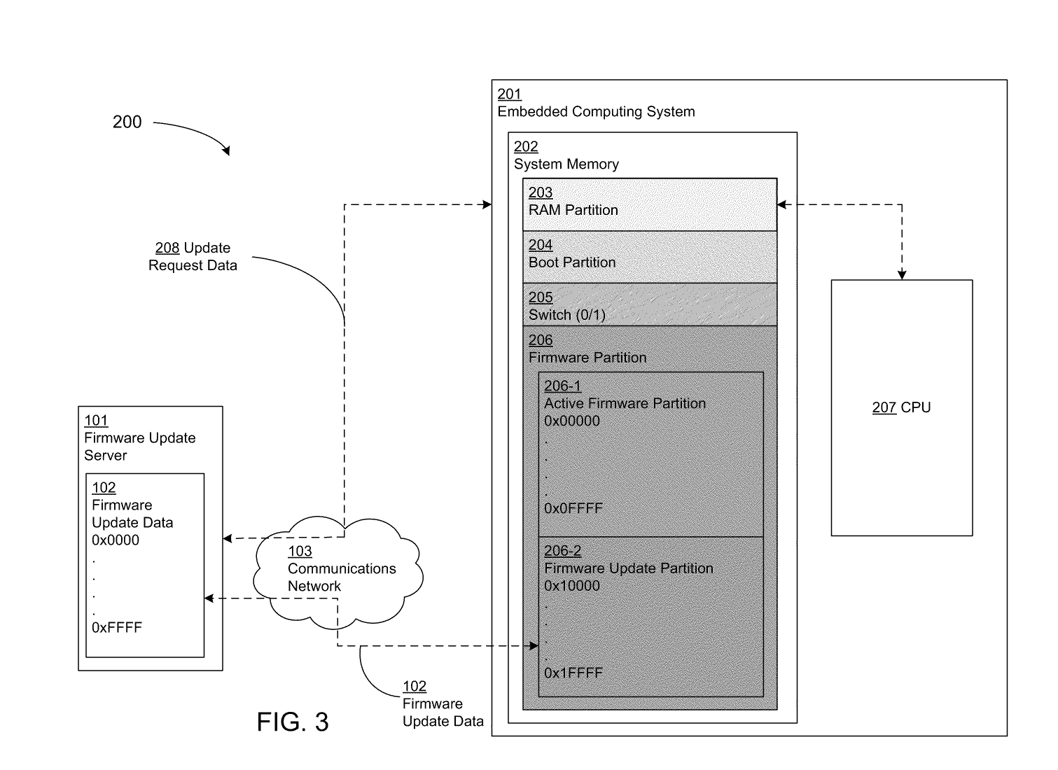

Referring to FIGS. 3-6, a reliable firmware updating system 200 may include a firmware update server 101, a communications network 103 and an embedded computing system 201. The firmware update server 101 may maintain firmware update data 102 which may be provided to the embedded computing system 201.

The embedded computing system 201 may include a system memory 202 and a processing unit 207. The system memory 202 may include a RAM partition 203, a boot partition 204, a firmware transfer switch 205 and a firmware partition 206.

The RAM partition 203 may include executable instructions for conducting firmware updates.

The boot partition 204 may include executable instructions for initializing the embedded computing system 201 so as to enable the embedded computing system 201 carry out its designed function as implemented by the instructions maintained in the firmware partition 206.

The processing unit 207 may include application specific integrated circuitry or configurable general purpose circuitry which may be configured to execute computer readable instructions stored in the system memory 202.

The firmware transfer switch 205 may include a logical switch (e.g. a binary value maintained in non-volatile memory) which may regulate the ability of the embedded computing system 201 to boot to the firmware partition 206 via the boot partition 204 instructions.

The firmware partition 206 may include an active firmware partition 206-1 (e.g. a partition maintaining program instructions for execution by the processing unit 207 to carry out the designed functionality of the embedded computing system 201) and a firmware update partition 206-2 (e.g. a partition for storing firmware update instructions received from a firmware update server 101).

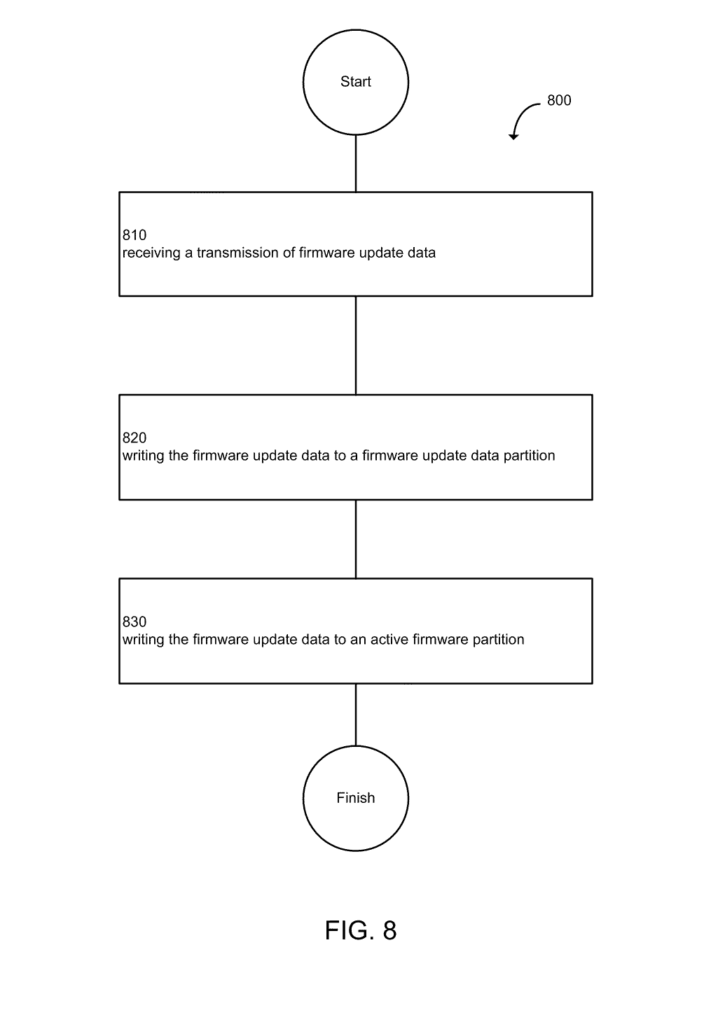

FIG. 8 illustrates an operational flow 800 representing example operations related to high-reliability firmware updating. In FIG. 8 and in following figures that include various examples of operational flows, discussion and explanation may be provided with respect to the above-described examples of FIGS. 3-7, and/or with respect to other examples and contexts. However, it should be understood that the operational flows may be executed in a number of other environments and contexts, and/or in modified versions of FIGS. 3-7. Also, although the various operational flows are presented in the sequence(s) illustrated, it should be understood that the various operations may be performed in other orders than those which are illustrated, or may be performed concurrently.

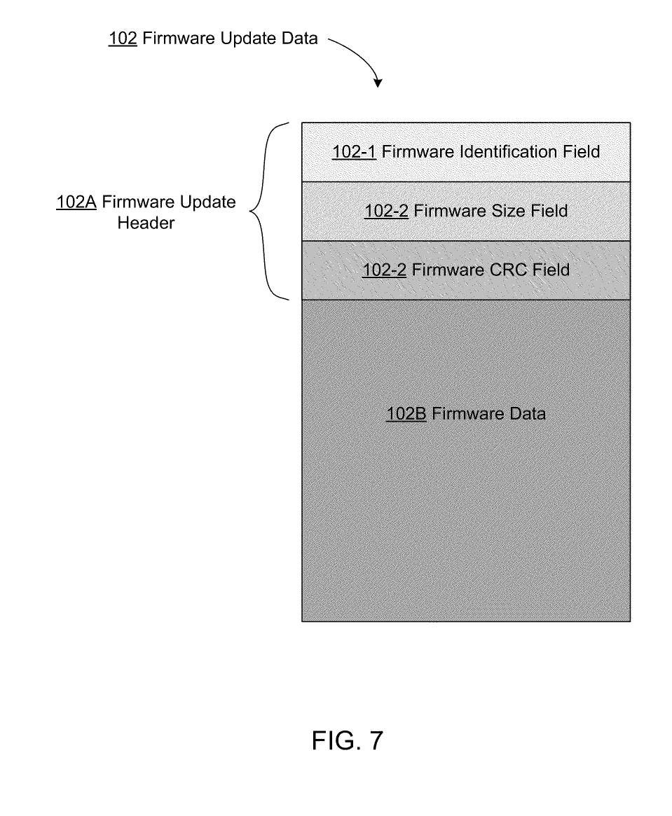

After a start operation, operation 810 depicts receiving a transmission of firmware update data. For example, as shown in FIG. 3, the processing unit 207 of the embedded computing system 201 may execute instructions stored in the system memory 202 (e.g. RAM partition 203) so as to cause the embedded computing system 201 to receive firmware update data 102 from a firmware update server 101 via a communications network 103. Referring to FIG. 7, the firmware update data 102 may comprise a firmware update header 102A and firmware data 102B. The firmware update header 102A may comprise one or more fields including, but not limited to, a firmware data identification field 102-1, a firmware size field 102-2 and/or a firmware cyclic redundancy check (CRC) field. The firmware data identification field 102-1, firmware size field 102-2 and/or the firmware CRC field 102-3 may provide data integrity certification capabilities so as to ensure the propriety of the transmitted firmware update data 102. For example, the firmware data identification field 102-1 may comprise a string of constant values indicating a file type or file extension so as to preliminarily determine that the data being transmitted is, in fact, firmware update data and not another incompatible file type (e.g. a spreadsheet document). The firmware size field 102-2 may be used to ensure complete transmission of the firmware update data 102 (e.g. the firmware size field 102-2 may be compared to the amount of data actually downloaded to the firmware update partition 206-2). The firmware CRC field 102-3 may specify a CRC function and the resultant output value which should be obtained when the specified CRC function is applied to the firmware data 102B.

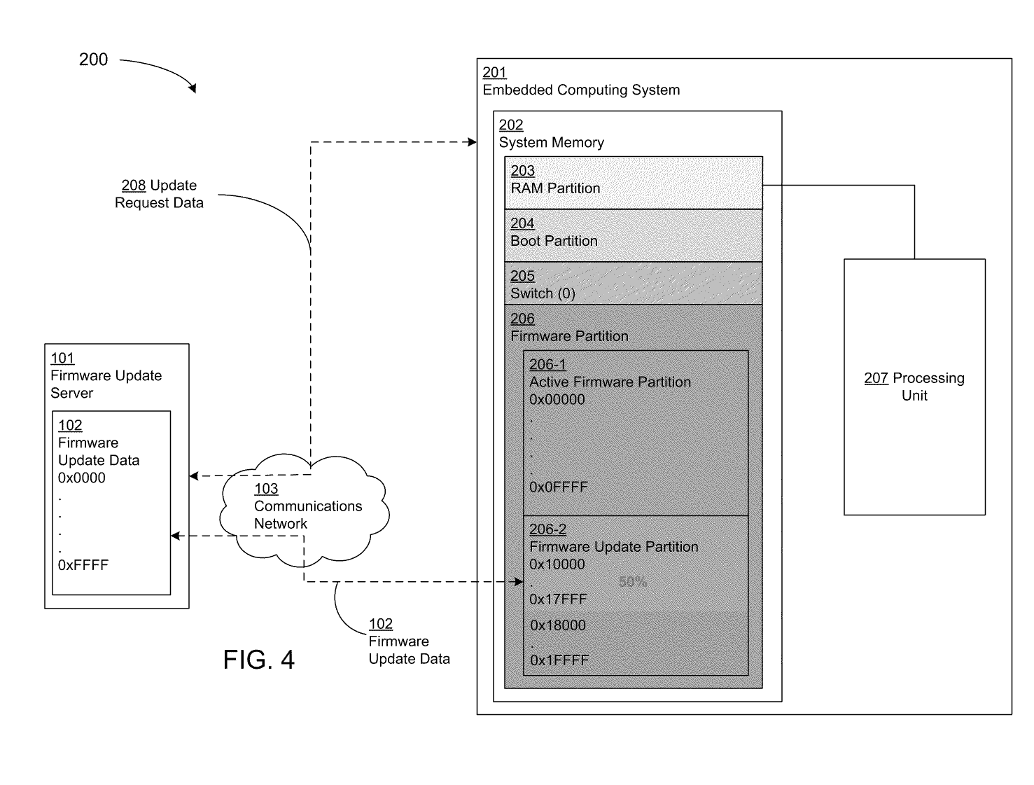

The operation 820 illustrates writing the firmware update data to a firmware update data partition. For example, as shown in FIG. 4, the processing unit 207 of the embedded computing system 201 may execute instructions stored in the system memory 202 so as to cause the embedded computing system 201 to write firmware update data 102 received from the firmware update server 101 to the firmware update partition 206-2 of the firmware partition 206.

The operation 830 illustrates writing the firmware update data to an active firmware partition. For example, as shown in FIG. 4, the processing unit 207 of the embedded computing system 201 may execute instructions stored in the system memory 202 so as to cause the embedded computing system 201 to write the firmware update data 102 previously written to the firmware update partition 206-2 to the active firmware partition 206-1.

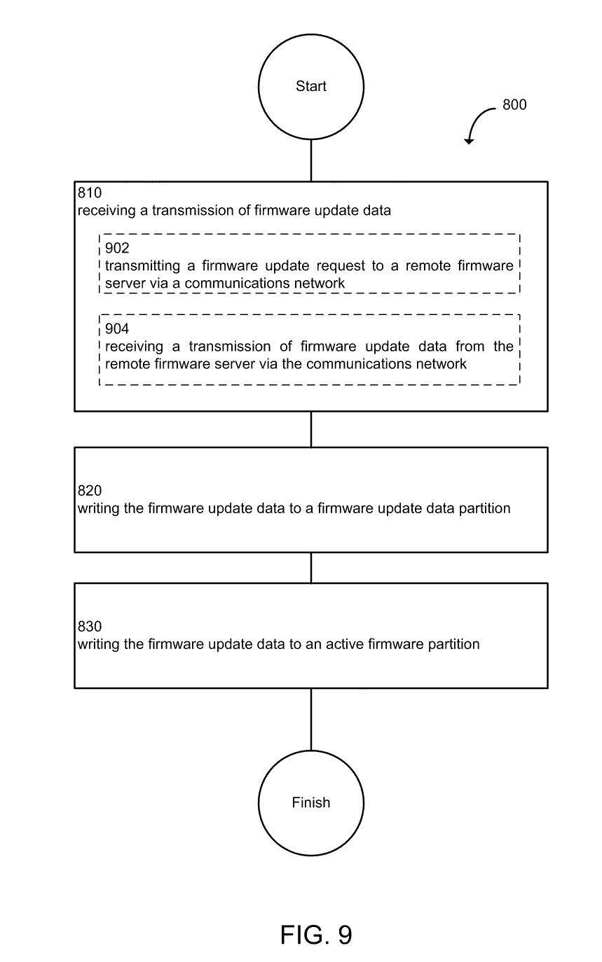

FIG. 9 illustrates alternative embodiments of the example operational flow 800 of FIG. 8. FIG. 9 illustrates example embodiments where the operational flow 800 may include at least one additional operation. Additional operations may include an operation 902, and/or an operation 904.

The operation 902 illustrates transmitting a firmware update request to a remote firmware server via a communications network. For example, as shown in FIG. 3, the processing unit 207 of the embedded computing system 201 may execute instructions stored in the system memory 202 so as to cause the embedded computing system 201 to transmit firmware update request data 208 to the firmware update server 101 via the communications network 103. The firmware update server 101 may, in turn, transmit the firmware update data 102 to the embedded computing system 201 via the communications network 103.

The operation 904 illustrates receiving a transmission of firmware update data from the remote firmware server via the communications network. For example, as shown in FIG. 3, the processing unit 207 of the embedded computing system 201 may execute instructions stored in the system memory 202 so as to cause the embedded computing system 201 to receive the firmware update data 102 from the firmware update server 101 via the communications network 103.

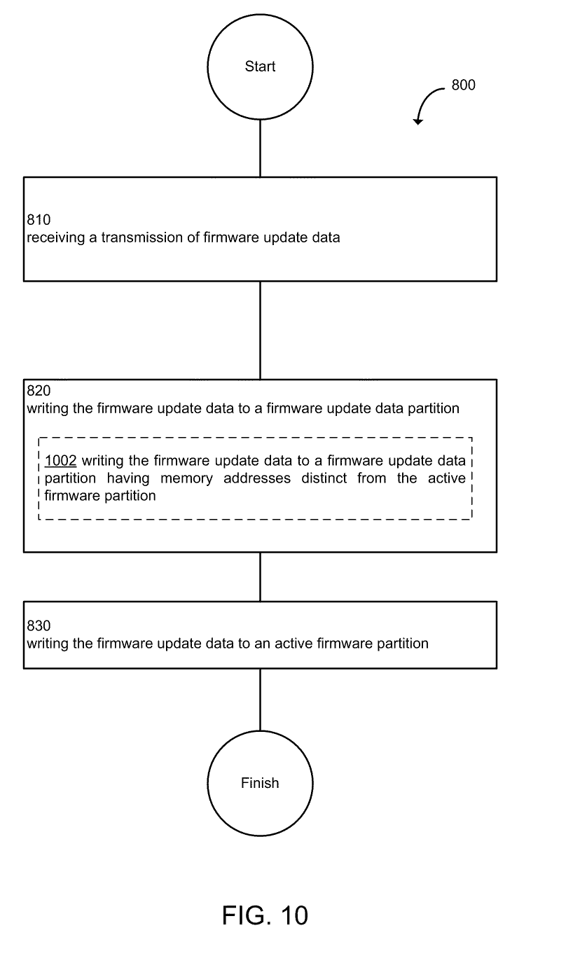

FIG. 10 illustrates alternative embodiments of the example operational flow 800 of FIG. 8. FIG. 10 illustrates example embodiments where the operational flow 800 may include at least one additional operation. Additional operations may include an operation 1002.

The operation 1002 illustrates writing the firmware update data to a firmware update data partition having memory addresses distinct from the active firmware partition. For example, as shown in FIGS. 3-6, the firmware partition 206 may include an active firmware partition 206-1 and a firmware update partition 206-2. The active firmware partition 206-1 may include a first set of memory addresses (e.g. addresses 0x00000 to 0X0FFFF) reserved solely for storage of firmware instructions to be executed by the processing unit 207 so as to implement the functionality of the embedded computing system 201. The firmware update partition 206-2 may include a second set of memory addresses (e.g. addresses 0x10000 to 0xFFFF) reserved solely for storage of uploaded firmware update data 102, such that uploading of the firmware update data 102 may have no effect on the execution of the active firmware instructions irrespective of the success or failure of the uploading of the firmware update data 102.

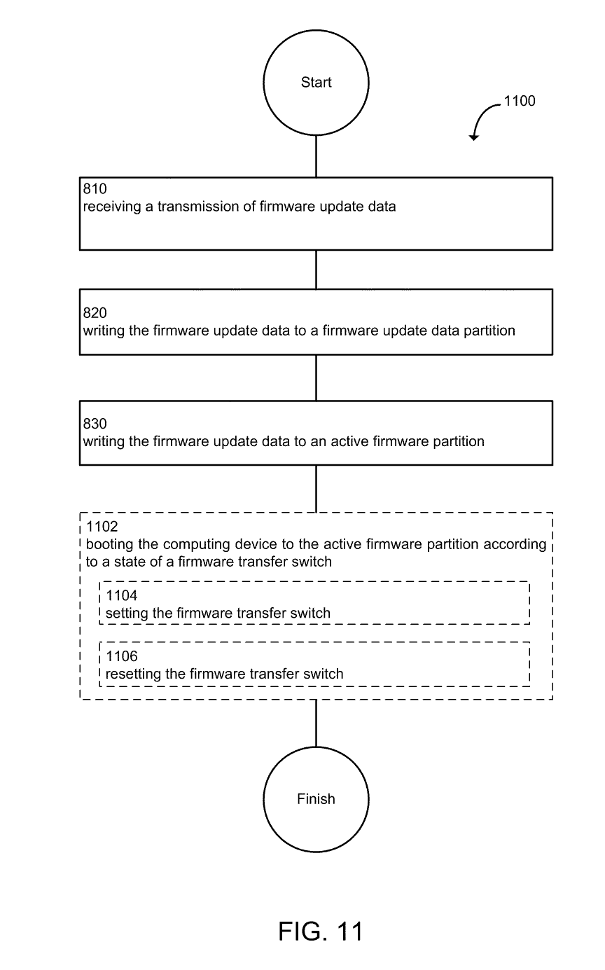

FIG. 11 illustrates example embodiments where an operational flow 1100 may include one or more operations of operational flow 800 as well as at least one additional operation. Additional operations may include an operation 1102, an operation 1104 and/or an operation 1106.

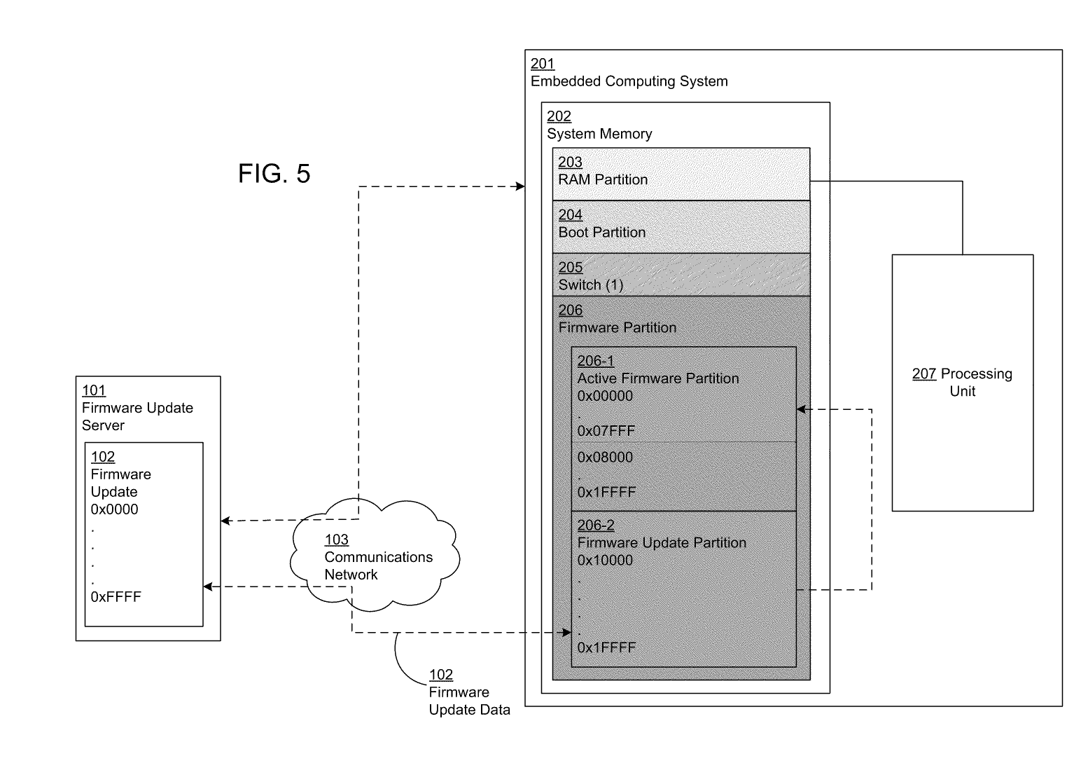

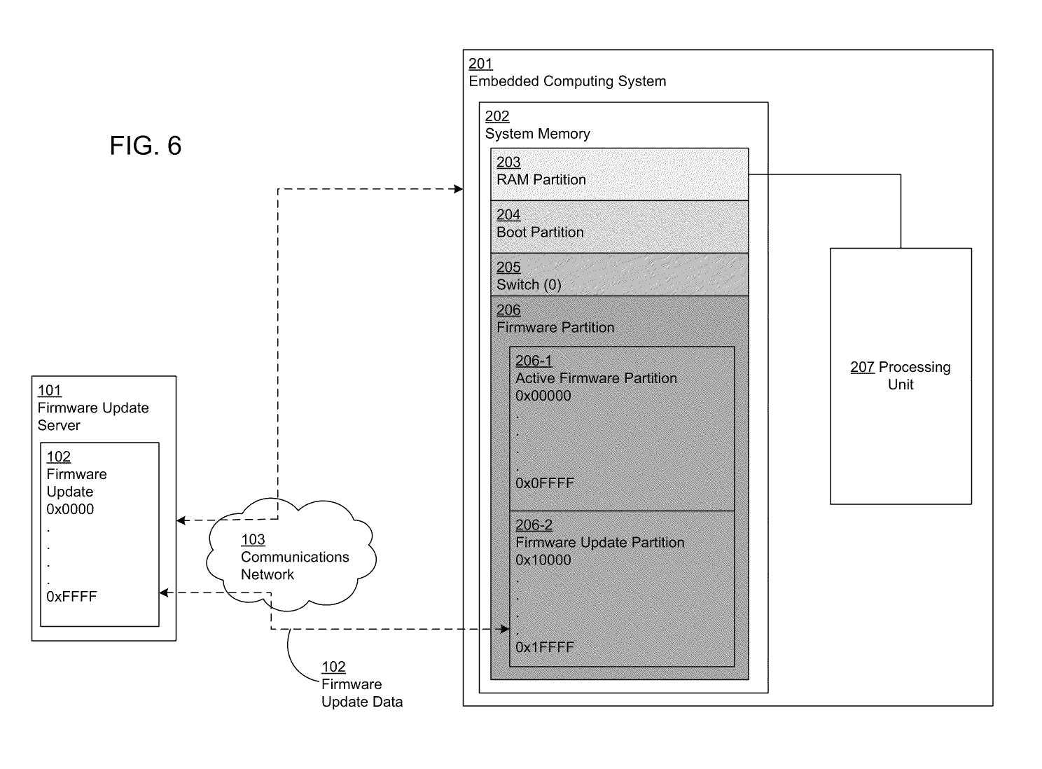

The operation 1102 illustrates booting the computing device to the active firmware partition according to a state of a firmware transfer switch. For example, as shown in FIGS. 5 and 6, the firmware transfer switch 205 value may be used to regulate the booting of the embedded computing system 201 to the active firmware partition 206-1. Under normal operating conditions, the firmware transfer switch 205 may be set to a logical ‘0.’ In such a condition, the processing unit 207 of the embedded computing system 201 may execute instructions stored in the boot partition 204 of the system memory 202 so as to cause the embedded computing system 201 to boot to the active firmware partition 206-1.

The operation 1104 illustrates setting the firmware transfer switch. For example as shown in FIGS. 4 and 5, upon complete receipt of the firmware update data 102 from the from the firmware update server 101 and a confirmation of the completion of its transfer to firmware update partition 206-2 (as described further below), the processing unit 207 of the embedded computing system 201 may execute instructions stored in the system memory 202 so as to cause the embedded computing system 201 to set the firmware transfer switch 205. As shown in FIG. 4, during transfer of the firmware update data 102 from the firmware update server 101 to the firmware update partition 206-2, the firmware transfer switch 205 may be set to a logical value of ‘0.’ As shown in FIG. 5, upon completion of the transfer of the firmware update data 102 from the firmware update server 101 to the firmware update partition 206-2, the firmware transfer switch 205 may be set to a logical value of ‘1.’ In such a condition, the processing unit 207 of the embedded computing system 201 may restrict executing program instructions from the active firmware partition 206-1 so as to allow for the transfer of the firmware update data 102 from the firmware update partition 206-2 to the active firmware partition 206-1. Should an interruption of the transfer of the firmware update data 102 from the firmware update partition 206-2 to the active firmware partition 206-1 occur, upon a restart of the embedded computing system 201, the processing unit 207 may detect the state of the firmware transfer switch 205 and either restart or continue the transfer of the firmware update data 102 from the firmware update partition 206-2 to the active firmware partition 206-1 as opposed to attempting to boot from the boot partition 204 to a partially updated active firmware partition 206-1.

The operation 1106 illustrates resetting the firmware transfer switch. For example, as shown in FIG. 6, upon completion of the transfer of the firmware update data 102 from the firmware update partition 206-2 to the active firmware partition 206-1, the firmware transfer switch 205 may be reset to a logical ‘0.’ In such a condition, the processing unit 207 of the embedded computing system 201 may again execute instructions stored in the boot partition 204 of the system memory 202 so as to cause the embedded computing system 201 to boot to a fully updated active firmware partition 206-1.

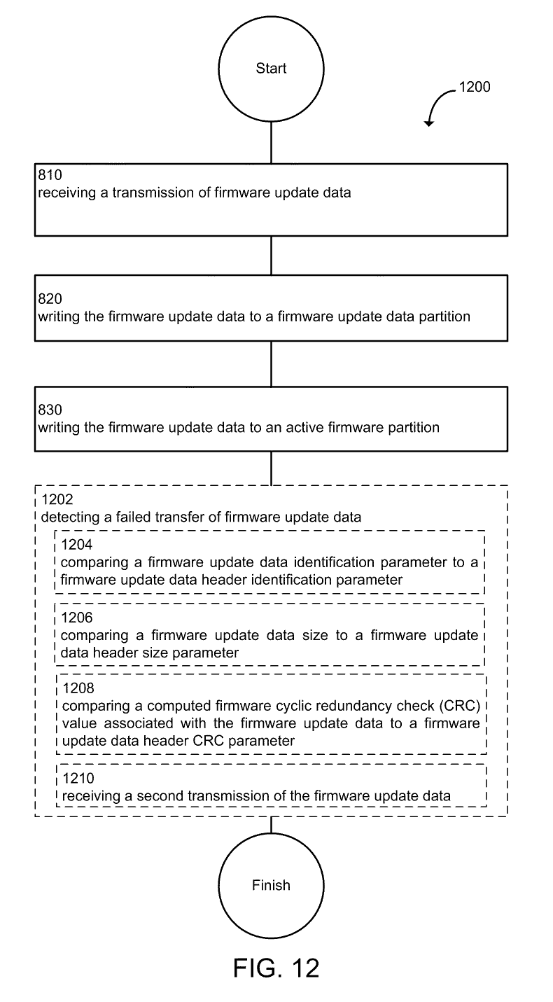

FIG. 12 illustrates example embodiments where an operational flow 1200 may include one or more operations of operational flow 800 as well as at least one additional operation. Additional operations may include an operation 1202, an operation 1204, an operation 1206, an operation 1208 and/or an operation 1210.

The operation 1202 illustrates detecting a failed transfer of firmware update data. For example, as shown in FIG. 4, the transfer of the firmware data 102B to the firmware update partition 206-2 may be disrupted (e.g. as a result of a power outage) resulting in an incomplete transfer of the firmware data 102B to the firmware update partition 206-2 (e.g. a transfer of only 50% of the firmware data 102B). The transfer of the firmware data 102B may be considered failed as the use of incomplete firmware data 102B in the active firmware partition 206-1 may result in an unknown state of the embedded computing system 201. As such, the processing unit 207 of the embedded computing system 201 may execute instructions stored in the system memory 202 so as to cause the embedded computing system 201 to detect a failed transfer of the firmware data 102B to the firmware update partition 206-2.

The operation 1204 illustrates comparing a firmware update data identification parameter to a firmware update data header identification parameter. For example, as shown in FIGS. 3-7, the firmware update data 102 may comprise a firmware update header 102A. The firmware update header 102A may comprise one or more fields including, but not limited to, a firmware data identification field 102-1. The firmware data identification field 102-1 may provide data integrity certification capabilities so as to ensure the propriety of the transmitted firmware update data 102. For example, the firmware data identification field 102-1 may comprise a string of constant values indicating a file type or file extension for allowing for a determination that the data being transmitted is, in fact, firmware update data and not another incompatible file type (e.g. a spreadsheet document). Should the value maintained in the firmware data identification field 102-1 not match a designated file-type associated with proper firmware update data 102, the processing unit 207 may recognize the transfer as failed.

The operation 1206 illustrates comparing a firmware update data size to a firmware update data header size parameter. For example, as shown in FIGS. 3-7, the firmware update data 102 may comprise a firmware update header 102A. The firmware update header 102A may comprise one or more fields including, but not limited to, a firmware size field 102-2. The firmware size field 102-2 may be used to ensure complete transmission of the firmware update data 102 (e.g. the firmware size field 102-2 may be compared to the amount of data actually transferred to the firmware update partition 206-2). Should the value maintained in the firmware size field 102-2 not match the actual size of the firmware update data 102 transferred to the firmware update partition 206-2, the processing unit 207 may recognize the transfer as failed.

The operation 1208 illustrates comparing a computed firmware cyclic redundancy check (CRC) value associated with the firmware update data to a firmware update data header CRC parameter. For example, as shown in FIGS. 3-7, the firmware update data 102 may comprise a firmware update header 102A. The firmware update header 102A may comprise one or more fields including, but not limited to, a firmware CRC field 102-3. The firmware CRC field 102-3 may specify a CRC function and the resultant output value which should be obtained when the specified CRC function is applied to the firmware data 102B. Should the CRC value maintained in the firmware CRC field 102-3 not match the actual output of the CRC function when applied to the firmware update data 102 transferred to the firmware update partition 206-2, the processing unit 207 may recognize the transfer as failed.

The operation 1210 illustrates receiving a second transmission of the firmware update data. For example, as shown in FIGS. 3-7, the transfer of the firmware data 102B to the firmware update partition 206-2 may be disrupted (e.g. as a result of a power outage) resulting in an incomplete transfer of the firmware data 102B to the firmware update partition 206-2 (e.g. a transfer of only 50% of the firmware data 102B). The transfer of the firmware data 102B may be considered failed as the use of incomplete firmware data 102B in the active firmware partition 206-1 may result in an unknown state of the embedded computing system 201. As such, the processing unit 207 of the embedded computing system 201 may execute instructions stored in the system memory 202 so as to cause the embedded computing system 201 to receive a retransmission of the firmware data 102B. The retransmitted firmware data 102B may overwrite any failed firmware update data previously stored firmware update partition 206-2 without any adverse affects on the normal operations of the embedded computing system 201.

It should be noted that many functions have been attributed to respective processing logic. However, such recitations are for descriptive purposes only and one skilled in the art will recognize that the various operations may be allocated to or implemented with one or more processing logic in an integrated or distributed manner without departing from the scope of the descriptions herein.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples can be implemented, individually and/or collectively, by a wide range of hardware, software, firmware, or virtually any combination thereof. In one embodiment, several portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and or firmware would be well within the skill of one of skill in the art in light of this disclosure.

In addition, those skilled in the art will appreciate that the mechanisms of the subject matter described herein are capable of being distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a Compact Disc (CD), a Digital Video Disk (DVD), a digital tape, a computer memory, etc.; and a transmission type medium such as a digital and/or an analog communication medium (e.g., a fiber optic cable, a waveguide, a wired communications link, a wireless communication link (e.g., transmitter, receiver, transmission logic, reception logic, etc.), etc.).

Those having skill in the art will recognize that the state of the art has progressed to the point where there is little distinction left between hardware, software, and/or firmware implementations of aspects of systems; the use of hardware, software, and/or firmware is generally (but not always, in that in certain contexts the choice between hardware and software can become significant) a design choice representing cost vs. efficiency tradeoffs. Those having skill in the art will appreciate that there are various vehicles by which processes and/or systems and/or other technologies described herein can be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be effected, none of which is inherently superior to the other in that any vehicle to be utilized is a choice dependent upon the context in which the vehicle will be deployed and the specific concerns (e.g., speed, flexibility, or predictability) of the implementer, any of which may vary. Those skilled in the art will recognize that optical aspects of implementations will typically employ optically-oriented hardware, software, and or firmware.

It is believed that the present invention and many of its attendant advantages will be understood by the foregoing description. It is also believed that it will be apparent that various changes may be made in the form, construction and arrangement of the components thereof without departing from the scope and spirit of the invention or without sacrificing all of its material advantages. The form herein before described being merely an explanatory embodiment thereof. It is the intention of the following claims to encompass and include such changes.

What is claimed is:

1. A method for updating computing device firmware comprising:
receiving a transmission of firmware update data;
writing the firmware update data to a firmware update data partition; and
writing the firmware update data to an active firmware partition.

2. The method of claim 1, wherein the receiving a transmission of firmware update data further comprises:
transmitting a firmware update request to a remote firmware server via a communications network; and
receiving a transmission of firmware update data from the remote firmware server via the communications network.

3. The method of claim 1, wherein the writing the firmware update data to a firmware update data partition further comprises:
writing the firmware update data to a firmware update data partition having memory addresses distinct from the active firmware partition.

4. The method of claim 1, further comprising:
booting the computing device to the active firmware partition according to a state of a firmware transfer switch.

5. The method of claim 4, wherein the booting the computing device to the active firmware partition according to a state of a firmware transfer switch further comprises:
setting the firmware transfer switch.

6. The method of claim 5, wherein the booting the computing device to the active firmware partition according to a state of a firmware transfer switch further comprises:
resetting the firmware transfer switch.

7. The method of claim 1, further comprising:
detecting a failed transfer of firmware update data.

8. The method of claim 7, wherein the detecting a failed transfer of firmware update data further comprises:
comparing a firmware update data identification parameter to a firmware update data header identification parameter.

9. The method of claim 7, wherein the detecting a failed transfer of firmware update data further comprises:
comparing a firmware update data size to a firmware update data header size parameter.

10. The method of claim 7, wherein the detecting a failed transfer of firmware update data further comprises:
comparing a computed firmware cyclic redundancy check (CRC) value associated with the firmware update data to a firmware update data header CRC parameter.

11. The method of claim 7, further comprising:
receiving a second transmission of the firmware update data.

12. A system for updating computing device firmware comprising:
means for receiving a transmission of firmware update data;
means for writing the firmware update data to a firmware update data partition; and
means for writing the firmware update data to an active firmware partition.

13. The system of claim 12, wherein the means for receiving a transmission of firmware update data further comprises:
means for transmitting a firmware update request to a remote firmware server via a communications network; and
means for receiving a transmission of firmware update data from the remote firmware server via the communications network.

14. The system of claim 12, wherein the means for writing the firmware update data to a firmware update data partition further comprises:
means for writing the firmware update data to a firmware update data partition having memory addresses distinct from the active firmware partition.

15. The system of claim 12, further comprising:
means for booting the computing device to the active firmware partition according to a state of a firmware transfer switch.

16. The system of claim 15, wherein the means for booting the computing device to the active firmware partition according to a state of a firmware transfer switch further comprises:
means for setting the firmware transfer switch.

17. The system of claim 16, wherein the means for booting the computing device to the active firmware partition according to a state of a firmware transfer switch further comprises:
means for resetting the firmware transfer switch.

18. The system of claim 12, further comprising:
means for detecting a failed transfer of firmware update data.

19. The system of claim 18, wherein the means for detecting a failed transfer of firmware update data further comprises:
means for comparing a firmware update data identification parameter to a firmware update data header identification parameter.

20. The system of claim 18, wherein the means for detecting a failed transfer of firmware update data further comprises:
means for comparing a firmware update data size to a firmware update data header size parameter.

21. The system of claim 18, wherein the means for detecting a failed transfer of firmware update data further comprises:
means for comparing a computed firmware cyclic redundancy check (CRC) value associated with the firmware update data to a firmware update data header CRC parameter.

22. The system of claim 18, further comprising:
means for receiving a second transmission of the firmware update data.

23. A computer-readable medium including computer readable program instructions comprising:
instructions for receiving a transmission of firmware update data;
instructions for writing the firmware update data to a firmware update data partition; and
instructions for writing the firmware update data to an active firmware partition.

24. The computer-readable medium of claim 23, wherein the instructions for writing the firmware update data to a firmware update data partition further comprise:
instructions for writing the firmware update data to a firmware update data partition having memory addresses distinct from the active firmware partition.

25. The computer-readable medium of claim 23, further comprising:
instructions for booting the computing device to the active firmware partition according to a state of a firmware transfer switch.
